(19) United States
(12) Patent Application Publication
(10) Pub. No.: US 2009/0258316 A1
(43) Pub. Date: Oct. 15, 2009

(54) METHOD FOR PATTERNING A COVERING MATERIAL BY USING HIGH-POWER EXCITING BEAM

(75) Inventors: Chung-Chih FENG, Kaohsiung (TW); Chun-Ta WANG, Kaohsiung (TW); Yung-Chang HUNG, Kaohsiung (TW); Wei-Te LIU, Kaohsiung (TW); I-Peng Yao, Kaohsiung (TW)

Correspondence Address: VOLENTINE & WHITT PLLC, ONE FREEDOM SQUARE, 11951 FREEDOM DRIVE SUITE 1260, RESTON, VA, 20190, US

(73) Assignee: SANG FANG CHEMICAL INDUSTRY CO., LTD., Kaohsiung (TW)

(21) Appl. No.: 12/189,833

(22) Filed: Aug. 12, 2008

(30) Foreign Application Priority Data
Apr. 11, 2008 (TW) 097113296

(51) Int. Cl. G03F 1/00

(52) U.S. Cl. 430/296

(57) ABSTRACT

The present invention relates to a method for patterning a covering material by using a high-power exciting beam. The method includes the steps of (a) providing a base material having a plurality of thin layers, the neighboring thin layers having different colors; and (b) utilizing a high-power exciting beam to form at least one pattern on the base material, in which the pattern has at least one concave portion, so as to expose the thin layers with different colors. As a result, the covering material has a layered visual effect and many colors. Furthermore, the patterning method of the present invention is simple, and can form the pattern on the base material easily Therefore, the manufacturing time of the covering material with the pattern is reduced.

### BACKGROUND OF THE INVENTION

1. Field of the Invention

The present invention relates to a method for patterning a covering material, and more particularly to a method for patterning a covering material by using a high-power exciting beam.

2. Description of the Related Art

R.O.C. Patent Publication No. 200706361 discloses a method for fabricating a polyurethane (PU) leather with a polycarbonate (PC) film, wherein a high-temperature resistant PU resin with pigments is first coated on an embossed release paper, and is dried in an oven. Then, a high-temperature resistant PU adhesive layer with pigments is coated, and is oven-baked to half dry. After that, a PC film is attached, and the whole piece is curled and cured. Finally, the release paper is removed to obtain a patterned PU leather.

Generally speaking, in the prior art, the pattern on the surface of a covering material with colorful graphics is formed by attaching an embossed release paper with textures and patterns onto a PC film. However, in this manner, the textures and patterns remain unchanged, so the covering material lacks the layered visual effect. Moreover, the conventional method for patterning the surface of a covering material is complex, and needs plenty of time to manufacture the covering material with the pattern.

Consequently, there is an existing need for providing a method for patterning a covering material by using a high-power exciting beam to solve the above-mentioned problems.

### SUMMARY OF THE INVENTION

Accordingly, the present invention is directed to a method for patterning a covering material by using a high-power exciting beam. The s method includes the steps of (a) providing a base material having a plurality of thin layers, and the neighboring thin layers having different colors; and (b) utilizing a high-power exciting beam to form at least one pattern on the base material, in which the pattern has at least one concave portion, so as to expose the thin layers with different colors.

In the method for patterning a covering material according to the present invention, the high-power exciting beam is utilized to form a pattern having a plurality of concave portions with different depths on the base material. The neighboring thin layers in the base material have different colors, so the concave portions of the pattern may expose the thin layers with different colors. As a result, the covering material has obvious layered visual effect and many colors. Furthermore, the patterning method of the present invention is simple, and can form the pattern on the base material easily. Therefore, the manufacturing time of the covering material with the pattern is reduced.

### BRIEF DESCRIPTION OF THE DRAWINGS

FIG. 1 is a flow chart of a method for patterning a covering material by using a high-power exciting beam according to the present invention; and

FIG. 2 is a schematic view of using the high-power exciting beam to form a pattern on the covering material according to the present invention.

### DETAILED DESCRIPTION OF THE INVENTION

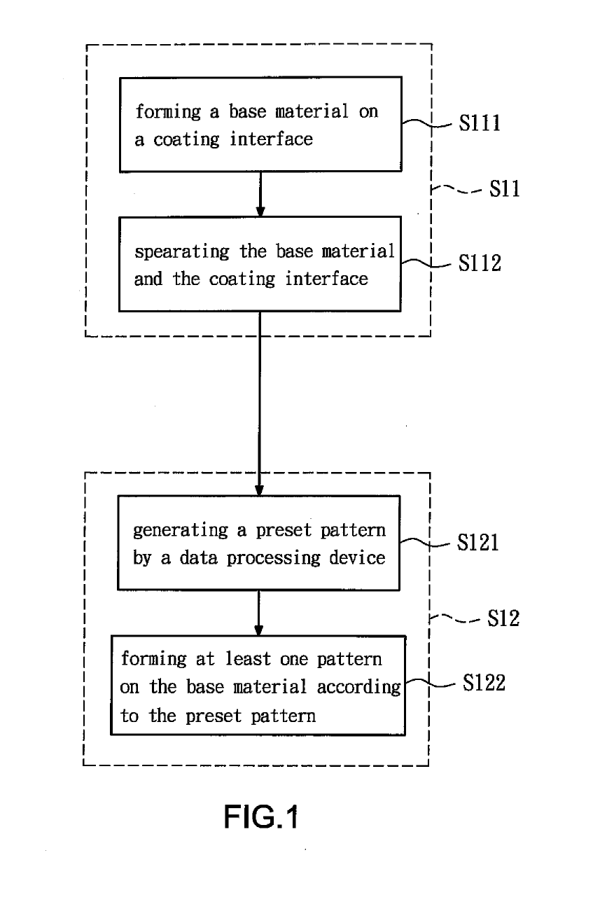

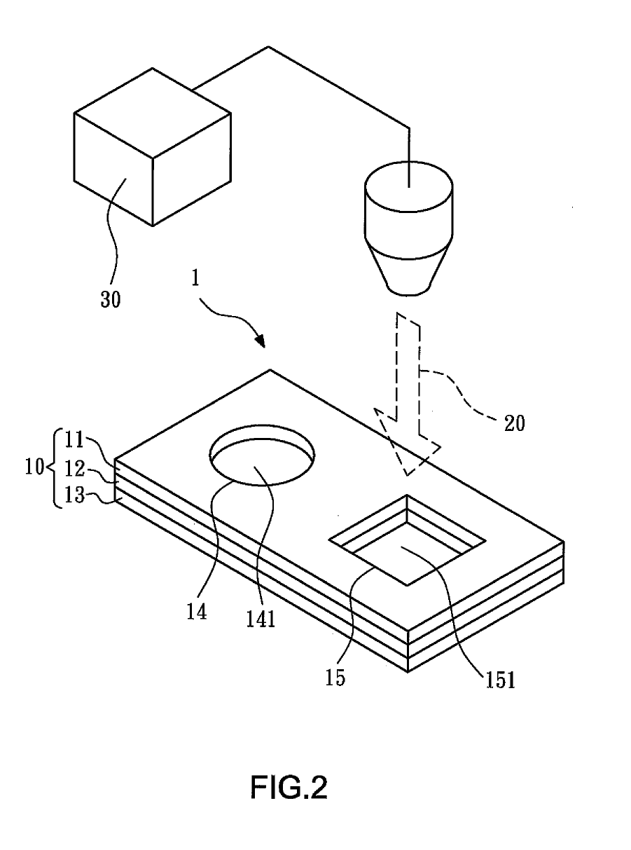

FIG. 1 is a flow chart of a method for patterning a covering material by using a high-power exciting beam according to the present invention. FIG. 2 is a schematic view of using the high-power exciting beam to form a pattern on the covering material according to the present invention. As shown in FIGS. 1 and 2, first, in Step S11, a base material 10 having a plurality of thin layers is provided, and the neighboring thin layers have different colors. In this embodiment, the base material 10 has a first thin layer 11, a second thin layer 12, and a third thin layer 13 with different colors. Further, in this embodiment, the first thin layer 11, the second thin layer 12, and the third thin layer 13 are made of polyurethane (PU), polypropylene (PP), polyethylene terephthalate (PET), or polymer resin. In addition, a polycarbonate (PC), acrylonitrile-butadience styrene (ABS), or a mixture of ABS and PC may be further bonded to the base material.

In this embodiment, the base material 10 is formed by the following steps. First, in Step S111, the base material 10 is formed on a coating interface, for example, an embossed release paper (not shown). Then, in Step S112, the base material 10 is separated from the coating interface. The first thin layer 11, the second thin layer 12, and the third thin layer 13 are disposed on the coating interface through several times of coating, so as to form the base material 10. It should be noted that in this embodiment, the PC material is bonded to the base material 10 before the base material 10 is separated from the coating interface.

Next, in Step S12, a high-power exciting beam 20 is utilized to form at least one pattern on the base material 10. The high-power exciting beam employed is generated by a laser device. The laser device may have a platform and a laser head. The base material 10 is disposed on the platform, and the platform moves relative to the laser head. That is to say, in the operation mode of the platform and the laser head, one is fixed, and the other moves (for example, the platform is fixed, and the laser head is movable; or the laser head is fixed, and the platform is movable). The pattern has at least one concave portion, so as to expose the first thin layer 11, the second thin layer 12, and the third thin layer 13 with different colors. In this embodiment, the high-power exciting beam 20 forms a first pattern 14 and a second pattern 15 (not limited to two patterns) on the base material 10. The first pattern 14 and the second pattern 15 respectively have a first concave portion 141 and a second concave portion 151 with different depths. In addition, the first concave portion 141 exposes the second thin layer 12, and the second concave portion 151 exposes the third thin layer 13, so as to show different colors.

It should be noted that, in other applications, the high-power exciting beam 20 forms at least one pattern on the base material 10. The same pattern may have a plurality of concave portions with different depths, so as to expose the thin layers with different colors and meanwhile display the pattern with a plurality of colors.

In this embodiment, the first pattern 14 and the second pattern 15 on the base material 10 are formed by the following steps. First, in Step S121, a data processing device 30 is provided. Then, a preset pattern corresponding to the first pattern 14 and the second pattern 15 is generated by the data processing device 30. In Step S122, the data processing device 30 controls the high-power exciting beam 20 to form the first pattern 14 and the second pattern 15 on the base material 10 according to the preset pattern.

Moreover, the data processing device 30 is a device with executable programs, for example, a computer. The data processing device 30 controls the power of the high-power exciting beam 20 to form the first pattern 14 and the second pattern 15 on the base material 10, so that the first pattern 14 and the second pattern 15 respectively have the first concave portion 141 and the second concave portion 151 with different depths. Thus, the covering material 1 of the present invention is completed. In addition, the covering material 1 of the present invention may be used to cover the surface of an electronic device, but is not limited to be used to cover the surface of an electronic device.

In the patterning method for a covering material according to the present invention, the high-power exciting beam 20 is utilized to form a pattern having at least one concave portion (the first concave portion 141 and the second concave portion 151 with different depths) on the base material 10. The neighboring thin layers in the base material 10 have different colors, so the concave portion (the first concave portion 141 and the second concave portion 151) of the pattern (the first pattern 14 and the second pattern 15) may expose the first thin layer 11, the second thin layer 12, and the third thin layer 13 with different colors. Whereby, the covering material 1 has layered visual effect and aplenty colors. Furthermore, the patterning method of the present invention is simple, and can form the pattern on the base material 10 easily. Therefore, the manufacturing time of the covering material 1 with the pattern is reduced.

While the embodiments of the present invention have been illustrated and described, various modifications and improvements can be made by those skilled in the art. The embodiments of the present invention are therefore described in an illustrative but not restrictive sense. It is intended that the present invention may not be limited to the particular forms as illustrated, and that all modifications that maintain the spirit and scope of the present invention are within the scope as defined in the appended claims.

1. A method for patterning a covering material by using a high-power exciting beam, comprising:
(a) providing a base material having a plurality of thin layers, wherein neighboring thin layers have different colors; and
(b) utilizing a high-power exciting beam to form at least one color pattern on the base material, wherein the color pattern is defined by at least one concave portion which is formed by the high-power exciting beam and which partially exposes thin layers of different colors within the base material.

2. The method according to claim 1, wherein in Step (a), the thin layers are made of polyurethane (PU), polypropylene (PP), polyethylene terephthalate (PET), or polymer resin.

3. The method according to claim 2, wherein in Step (a), a polycarbonate (PC), acrylonitrile-butadience styrene (ABS), or a mixture of ABS and PC is further bonded to the base material.

4. The method according to claim 1, wherein Step (a) further comprises:
(a1) forming the base material on a coating interface; and
(a2) separating the base material and the coating interface.

5. The method according to claim 4, wherein in Step (a1), the thin layers are disposed on the coating interface through several times of coating, so as to form the base material.

6. The method according to claim 4, wherein in Step (a1), the coating interface is an embossed release paper.

7. The method according to claim 1, wherein the high-power exciting beam used in Step (b) is generated by a laser device, the laser device has a platform and a laser head, the base material is disposed on the platform, and the platform moves relative to the laser head.

8. The method according to claim 1, wherein in Step (b), the pattern has a plurality of concave portions, and the concave portions have different depths so as to expose respective thin layers of different colors.

9. The method according to claim 1, wherein in Step (b), the high-power exciting beam forms a plurality of patterns on the base material, each pattern has a concave portion, and the concave portions of the patterns have different depths so as to expose respective thin layers of different colors.

10. The method according to claim 1, wherein Step (b) further comprises:
(b1) providing a data processing device;
(b2) generating a preset pattern by the data processing device, wherein the preset pattern is corresponding to the pattern of the base material; and
(b3) controlling the high-power exciting beam by the data processing device to form the pattern on the base material according to the preset pattern.

11. The method according to claim 10, wherein in Step (b1), the data processing device is a device with executable programs.

12. The method according to claim 11, wherein in Step (b1), the data processing device is a computer.

13. The method according to claim 10, wherein in Step (b3), the data processing device controls the power of the high-power exciting beam to form the pattern on the base material, and thus the pattern has the concave portions with different depths.

14. The method according to claim 1, wherein the covering material covers the surface of an electronic device.

15. The method according to claim 8, wherein Step (b) further comprises:
(b1) providing a data processing device;
(b2) generating a preset pattern by the data processing device, wherein the preset pattern is corresponding to the pattern of the base material; and
(b3) controlling the high-power exciting beam by the data processing device to form the pattern on the base material according to the preset pattern.

16. The method according to claim 9, wherein Step (b) further comprises:
(b1) providing a data processing device;
(b2) generating a preset pattern by the data processing device, wherein the preset pattern is corresponding to the pattern of the base material; and
(b3) controlling the high-power exciting beam by the data processing device to form the pattern on the base material according to the preset pattern.
